(19) United States
(12) Patent Application Publication
(10) Pub. No.: US 2026/0018851 A1
(43) Pub. Date: Jan. 15, 2026

(54) SYSTEM AND METHOD FOR TESTING VCSEL DIE

(71) Applicant: PIXART IMAGING INC., Hsin-Chu County (TW)

(72) Inventors: Eng Khong TEOH, Penang (MY); Kwang Beng OOI, Penang (MY)

(21) Appl. No.: 18/767,984

(22) Filed: Jul. 10, 2024

(51) Int. Cl. H01S 5/00; H01S 5/068

(52) U.S. Cl. CPC H01S 5/0014; H01S 5/06812; H01S 5/06821

(57) ABSTRACT

There is provided a system for testing a VCSEL die including a first beam splitter, a second beam splitter, a first polarizer, a second polarizer, a first light sensor, a second light sensor and a third light sensor. The first beam splitter divides an emission light beam of the VCSEL die to a first light beam and a second light beam. The second beam splitter divides the second light beam to a third light beam and a fourth light beam. The first polarizer has a first polarization direction and is arranged for the third light beam to pass through. The second polarizer has a second polarization direction and is arranged for the fourth light beam to pass through. The first light sensor receives the first light beam. The second light sensor receives the polarized third light beam. The third light sensor receives the polarized fourth light beam.

### FIELD OF THE DISCLOSURE

This disclosure generally relates to testing laser devices and, more particularly, to a system and a method for testing the polarization stability of a vertical cavity surface emitting laser (VCSEL) die.

### BACKGROUND OF THE DISCLOSURE

When moving a VCSEL die from a wafer to a predetermined position, the VCSEL die can be damaged or rotated due to the parameter deviation of the pick and place equipment. Therefore, it is required to perform testing on the VCSEL die.

The conventional method to test polarization stability of a VCSEL die is to use an optical based goniometer system, which is impractical for production high-volume testing due extended test duration.

The information disclosed in this BACKGROUND is merely intended to increase understanding of the general background of the invention and should not be taken as an admission or in any way implied that the relevant information constitutes prior art that is already known to a person of ordinary skill in the art.

### SUMMARY

Accordingly, the present disclosure provides a system and a method that may test the polarization stability and die performance of a VCSEL die.

The present disclosure provides a system for testing a VCSEL die including a first beam splitter, a second beam splitter, a first polarizer, a second polarizer, a first light sensor, a second light sensor and a third light sensor. The first beam splitter is configured to split an emission light beam to a first light beam and a second light beam. The second beam splitter is configured to split the second light beam to a third light beam and a fourth light beam. The first polarizer has a first polarization direction and is configured for the third light beam to pass through. The second polarizer has a second polarization direction and is configured for the fourth light beam to pass through. The first light sensor is configured to receive the first light beam. The second light sensor is configured to receive the polarized third light beam. The third light sensor is configured to receive the polarized fourth light beam.

The present disclosure further provides a testing method of a system for testing a VCSEL die. The testing method includes the steps of: driving the VCSEL die using a driving current increased by a predetermined step; recording first light power data of the first light sensor, second light power data of the second light sensor, and third light power data of the third light sensor; identifying whether the first light power data fulfills a predetermined power requirement or not; calculating a second fitting curve of the second light power data and a third fitting curve of the third light power data upon the predetermined power requirement being fulfilled; calculating a second residual data according to the second light power data and the second fitting curve; and calculating a third residual data according to the third light power data and the third fitting curve.

The present disclosure further provides a testing method of a system for testing a VCSEL die. The system includes a first light sensor, a second light sensor and a third light sensor. The testing method includes the steps of: outputting non-polarized light power data by the first light sensor; outputting light power data associated with a first polarization direction by the second light sensor; outputting light power data associated with a second polarization direction by the third light sensor; identifying whether the non-polarized light power data fulfills a predetermined power requirement or not; and identifying polarization performance of the VCSEL die according to residual data and coefficients of determination of the light power data associated with the first and second polarization directions upon the predetermined power requirement being fulfilled.

### BRIEF DESCRIPTION OF DRAWINGS

Other objects, advantages, and novel features of the present disclosure will become more apparent from the following detailed description when taken in conjunction with the accompanying drawings.

FIG. 1 is a schematic diagram of a testing system for testing a VCSEL die according to one embodiment of the present disclosure.

FIGS. 2A and 2B are schematic diagrams of output power of light sensors of a testing system according to one embodiment of the present disclosure.

FIG. 3 is a partially enlarged schematic diagram of output power data of one light sensor in FIG. 2A.

FIG. 4 is a flow chart of a testing method of a system for testing a VCSEL die according to one embodiment of the present disclosure.

### DETAILED DESCRIPTION OF THE DISCLOSURE

It should be noted that, wherever possible, the same reference numbers will be used throughout the drawings to refer to the same or like parts.

One objective of the present disclosure is to provide a system and a testing method for testing the polarization stability of a vertical cavity surface emitting laser (VCSEL) die. The system uses a beam splitter to divide an emission light beam of a device under test (DUT) into a first light beam and a second light beam. The first light beam is directly received by a light sensor without passing a polarizer. The second light beam is split by another beam splitter, and the split light beams pass polarizers having different polarization directions to be received by different light sensors.

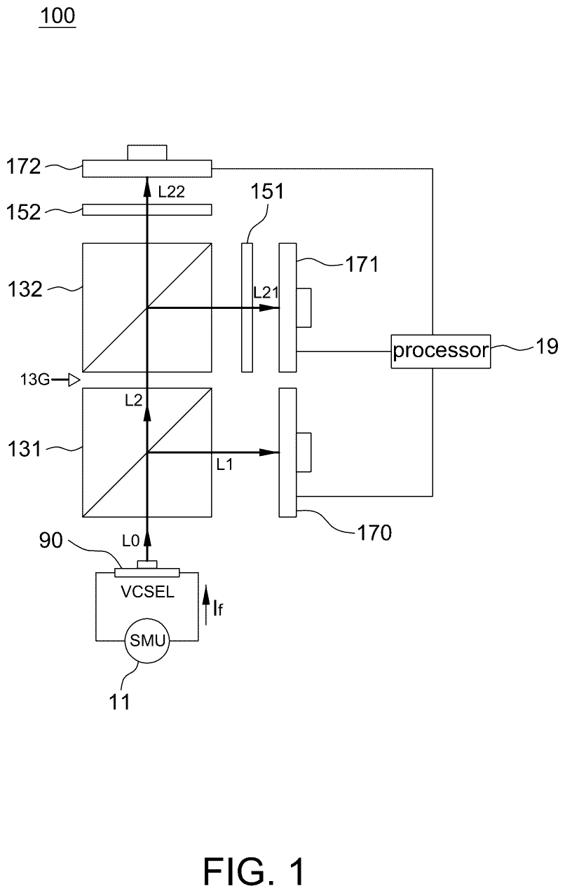

Please refer to FIG. 1, it is a schematic diagram of a testing system 100 for testing a VCSEL die according to one embodiment of the present disclosure. The testing system 100 is used to perform the failure/performance testing on a device under test (i.e. VCSEL die) 90.

The testing system 100 includes a first beam splitter 131, a second beam splitter 132, a first polarizer 151, a second polarizer 152, a first light sensor 170, a second light sensor 171, a third light sensor 172, a source measure unit (SMU) 11 and a processor 19. The first beam splitter 131 and the second beam splitter 132 are 50/50 beam splitters.

The first beam splitter 131 is used to split an emission light beam L0 of the VCSEL die 90 into a first light beam L1 and a second light beam L2. The second beam splitter 132 is used to split the second light beam L2 into a third light beam L21 and a fourth light beam L22. Furthermore, to reduce the energy loss of the second light beam L2, a distance between the first beam splitter 131 and the second beam splitter 132 in a propagating direction of the second light beam L2 (i.e. up and down directions in FIG. 1) is arranged as small as possible, e.g., smaller than 1 mm.

The first polarizer 171 has a first polarization direction and is arranged to allow the third light beam L21 to pass through. The second polarizer 152 has a second polarization direction and is arranged to allow the fourth light beam L22 to pass through. In one aspect, one of the first and second polarization directions is 45 degrees and the other one of the first and second polarization directions is 0 degrees. The present disclosure is described in the way that the first polarization direction is 45 degrees and the second polarization direction is 0 degrees as an example.

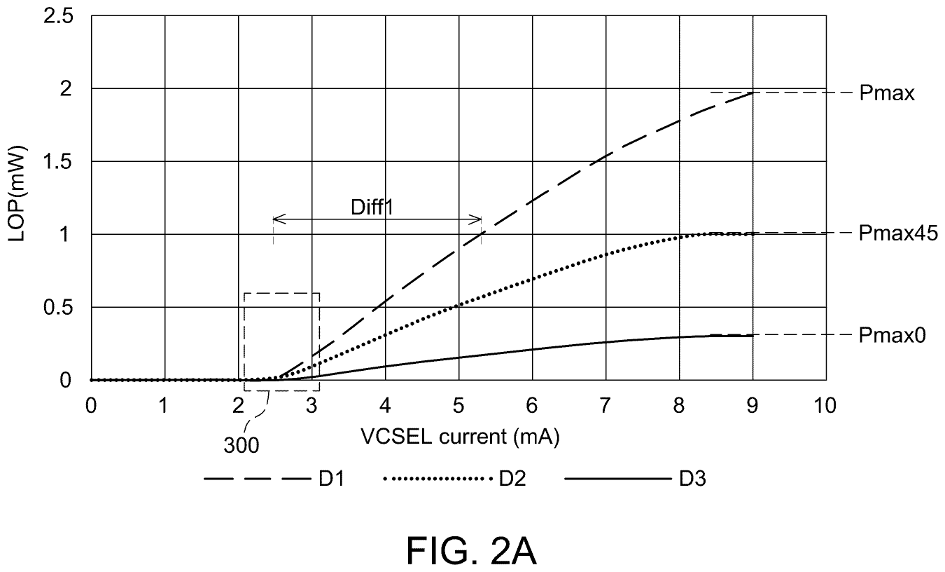

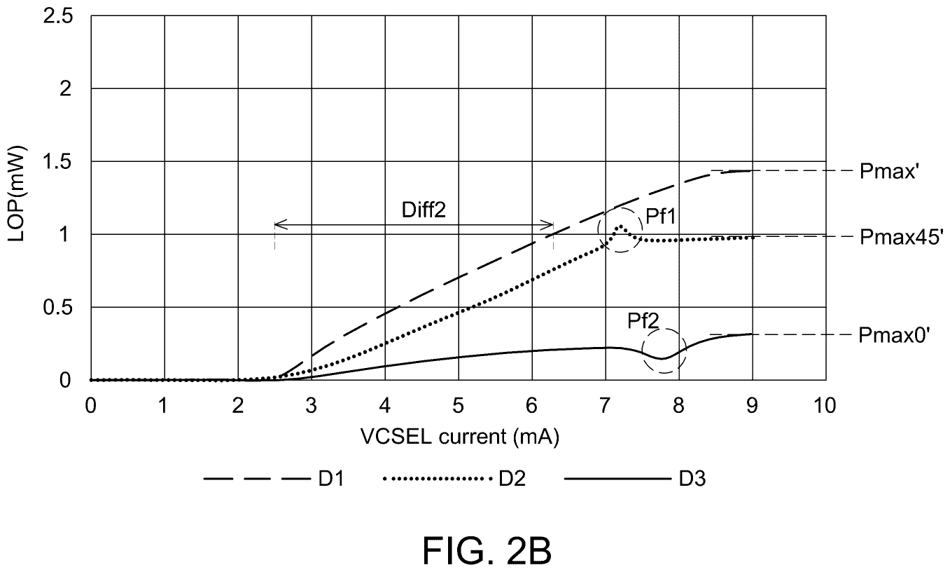

The first light sensor 170, the second light sensor 171 and the third light sensor 172 are optoelectronic devices to convert detected light energy to electrical signals, e.g., complementary metal oxide semiconductor (CMOS) image sensors, charge coupled device (CCD) image sensors or single photon avalanche diode (SPAD) sensors. The first light sensor 170 is used to receive the first light beam L1 to generate first light power data (e.g., D1 shown in FIGS. 2A and 2B) to the processor 19, wherein the first light power data is non-polarized light power data. The second light sensor 171 is used to receive the polarized third light beam L21 (indicated by the same reference numeral as the third light beam) to generate second light power data (e.g., D2 shown in FIGS. 2A and 2B) to the processor 19, wherein the second light power data is light power data associated with the first polarization direction. The third light sensor 172 is used to receive the polarized fourth light beam L22 (indicated by the same reference numeral as the fourth light beam) to generate third light power data (e.g., D3 shown in FIGS. 2A and 2B) to the processor 19, wherein the third light power data is light power data associated with the second polarization direction.

The source measure unit 11 is used to provide a driving current If to the VCSEL die 90, and the driving current If is monotonically increased by a predetermined step. In one aspect, the driving current If is increased from 0 to 9 mA, and the predetermined step is 50 μA. It is appreciated that if a smaller predetermined step is used, more data is sampled.

The processor 19 is, for example, a micro controller unit (MCU), a central processing unit (CPU), an application specific integrated circuit (ASIC) or a field programmable gate array (FPGA). The processor 19 post-processes the first light power data, the second light power data and the third light power data using software, firmware and/or hardware to identify performance of the DUT 90, e.g., including maximum output power and polarization stability.

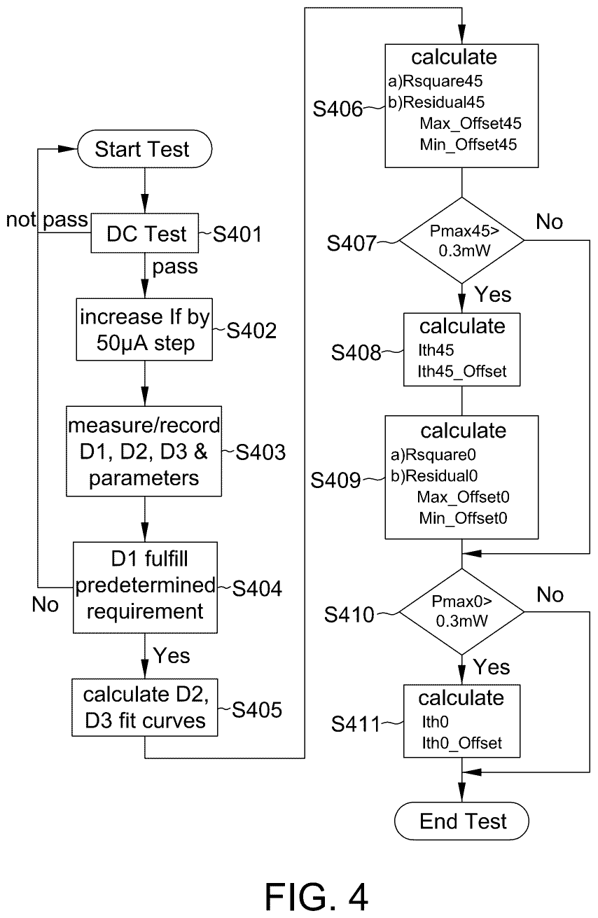

Please refer to FIG. 4, it is a flow chart of a testing method of the testing system 100 of an embodiment in FIG. 1. The testing method of this embodiment includes the steps mentioned below.

Step S401: After the testing is started, the VCSEL die 90 receives the DC test at first so as to confirm the failure device in an early stage. If the DC test is not passed, a next die will be tested. The DC test is known to the art and not a main objective of the present disclosure, and thus details thereof are not described herein.

Step S402: Next, the source measure unit 11 drives the VCSEL die 90 using the driving current If gradually increased by a predetermined step. As mentioned above, the driving current If is increased from 0 to 9 mA, and the predetermined step is 50 μA. In an interval that the VCSEL die 90 is driven, the first light sensor 170 outputs first light power data D1, the second light sensor 717 outputs second light power data D2 and the third light sensor 172 outputs third light power data D3, e.g., referring to FIG. 2A.

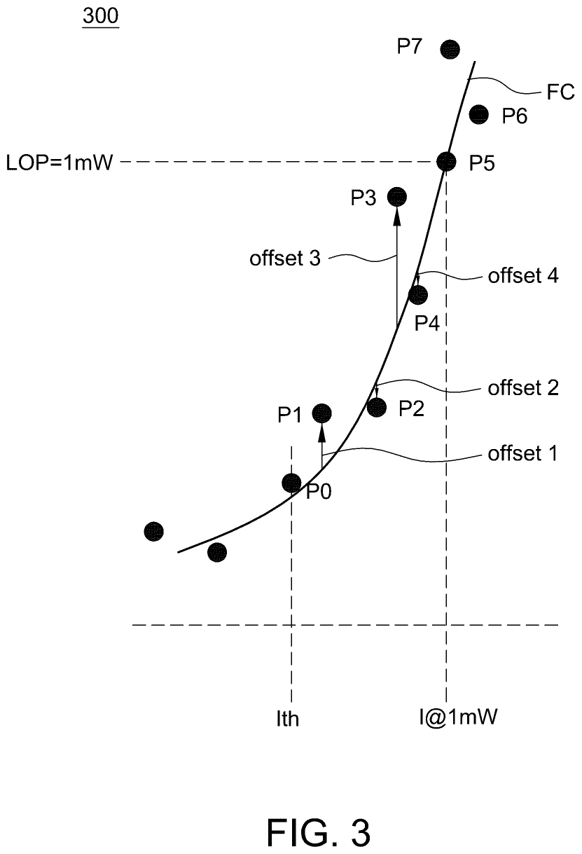

Step S403: Within the driving period, the processor 19 receives and records (e.g., in a memory thereof) the first light power data D1, the second light power data D2 and the third light power data D3 and related parameters thereof. In one aspect, the related parameters include a threshold current Ith (indicating a driving current If at which the light power is detected), a maximum power Pmax and a current at 1 mW power (e.g., shown as I@ 1 mW in FIG. 3, indicating a driving current If at which the light sensor having 1 mW output power) of the first light power data D1. The related parameters further include threshold currents Ith45 and Ith0, maximum power Pmax45 and Pmax0, and current at 1 mW power of the second light power data D2 and the third light power data D3.

Step S404: After the first light power data D1, the second light power data D2 and the third light power data D3 are obtained, the processor 19 firstly identifies whether the related parameters of the first light power data D1 fulfill a predetermined power requirement or not. For example, the processor 19 identifies whether the maximum power of the first light power data D1 is higher than a first power threshold. Referring to FIGS. 2A and 2B, if it is assumed that the first power threshold is 1.5 mW and when the maximum power exceeds the first power threshold (e.g., FIG. 2A showing Pmax>1.5 mW), the predetermined power requirement is satisfied; whereas, when the maximum power does not exceed the first power threshold (e.g., FIG. 2B showing Pmax′<1.5 mW), the predetermined power requirement is not satisfied. For example, the processor 19 identifies whether a difference between the threshold current Ith and the current at 1 mW power of the VCSEL die 90 fulfills a predetermined difference or not. For example, FIGS. 2A and 2B show that when the maximum power of the first light power data D1 is lower (e.g., Pmax′<Pmax), the difference between the threshold current Ith and the current at 1 mW power becomes larger (e.g., Diff2>Diff1). The first power threshold and the predetermined difference are previously determined according to, for example, the theoretical derivation and historical experience.

The Step S405 is entered when the related parameters of the first light power data D1 fulfill the predetermined power requirement; otherwise, the DUT 90 is identified not to meet the specification and then a next VCSEL die is tested.

Step S405: The processor 19 calculates a second fitting curve of the second light power data D2 and a third fitting curve of the third light power data D3. For example referring to FIG. 3, it is assumed that the light power data contains multiple data points P0 to P7 (only a part of data points being used as an example), and a fitting curve FC of the multiple data points P0 to P7 may be calculated, wherein the fitting curve may be a second order fitting curve, but not limited to second order. The light power data in FIG. 3 may be the second light power data D2 and the third light power data D3. The method of calculating the fitting curve FC may be those known to the art and thus details thereof are not described herein. For example, the processor 19 is embedded with a related algorithm, which respectively calculates a fitting curve of the second light power data D2 and the third light power data D3 while being run.

Step S406: Next, the processor 19 calculates second residual data (e.g., shown as Residual45) according to the second light power data D2 and the second fitting curve. The processor 19 further calculates a second coefficient of determination (e.g., shown as Rsquare45) according to the second light power data D2, the second fitting curve and the second coefficient of determination Rsquare45. The method of calculating the second residual data and the second coefficient of determination may use those known to the art, and thus details thereof are not described herein. The processor 19 calculates a maximum offset (e.g., shown as Max_offset45) and a minimum offset (e.g., shown as Min_offset45) according to the second residual data Residual45. FIG. 3 further shows offsets of some data points, e.g., offset1 to offset4, and the Max_offset45 is the largest one among these data points and the Min_offset45 is the smallest one of these data points.

Please refer to FIG. 2B, when the Max_offset45 is too large, a peak like Pf1 and a valley like Pf2 may appear, and it means that the polarization of the VCSEL die 90 has a problem. Therefore, in the present disclosure the processor 19 is arranged to compare the Max_offset45 with a second offset threshold as one judgment condition. Furthermore, the processor 19 is further arranged to compare the second coefficient of determination Rsquare45 with a second predetermined threshold (e.g., 0.95, but not limited to) as another judgment condition. These comparison results are recorded as testing results of the testing system 100.

Step S407 to S408: Next, the processor 19 identifies whether the maximum power Pmax45 of the second light power data D2 is larger than a second power threshold (e.g., shown as 0.3 mW, but not limited to 0.3 mW). If the Pmax45 is not higher than the second power threshold, the Step S410 is directly entered. If the Pmax45 is higher than the second power threshold, the processor 19 calculates a second threshold current offset (e.g., shown as Ith45_Offset, which is a difference from a predetermined threshold current or from the threshold current Ith of the first light power data D1) of the threshold current Ith45 according to the second light power data D2. Similarly, the maximum power Pmax45 and the second threshold current offset Ith45_Offset calculated according to the second light power data D2 represent the performance of 45-degree polarization direction of the VCSEL die 90. When the maximum power Pmax45 and the second threshold current offset Ith45_Offset exceed a predetermined range, it means that the VCSEL die 90 has a defect in manufacturing and positioning.

Step S409: Next, the processor 19 calculates third residual data (e.g., shown as Residual0) according to the third light power data D3 and the third fitting curve. The processor 19 further calculates a third coefficient of determination (e.g., shown as Rsquare0) according to the third light power data D3, the third fitting curve and the third coefficient of determination Rsquare0. The method of calculating the third residual data and the third coefficient of determination may use those known to the art, and thus details thereof are not described herein. The processor 19 calculates a maximum offset (e.g., shown as Max_offset0) and a minimum offset (e.g., shown as Min_offset0) according to the third residual data Residual0.

The processor 19 is arranged to compare the Max_offset0 with a third offset threshold (identical to or different from the second offset threshold) as one judgment condition. Furthermore, the processor 19 is further arranged to compare the third coefficient of determination Rsquare0 with a third predetermined threshold (identical to or different from the second predetermined threshold) as another judgment condition. These comparison results are recorded as testing results of the testing system 100.

Step S410 to S411: Next, the processor 19 identifies whether the maximum power Pmax0 of the third light power data D3 is larger than a third power threshold (e.g., shown as 0.3 mW, being identical to or different from the second power threshold). If the Pmax0 is not higher than the third power threshold, the processor 19 ends the testing and records all testing results. If the Pmax0 is higher than the third power threshold, the processor 19 calculates a third threshold current offset (e.g., shown as Ith0_Offset, which is a difference from a predetermined threshold current or from the threshold current Ith of the first light power data D1) of the threshold current Ith0 according to the third light power data D3. Similarly, the maximum power Pmax0 and the third threshold current offset Ith0_Offset calculated according to the third light power data D3 represent the performance of 0-degree polarization direction of the VCSEL die 90. When the maximum power Pmax0 and the third threshold current offset Ith0_Offset exceed a predetermined range, it means that the VCSEL die 90 has a defect in manufacturing and positioning.

In one aspect, the processor 19 is further used to identify whether the second light power data D2 (or the second maximum power Pmax45) is larger than the third light power data D3 (or the third maximum power Pmax0), i.e. as shown in FIG. 2A. When the second light power data D2 is smaller than the third light power data D3, it means that the VCSEL die 90 is rotated after the positioning process.

In brief, the algorithm embedded in the processor 19 firstly identifies whether the non-polarized light power data (e.g., D1) fulfills the predetermined power requirement. If D1 does not fulfill the requirement, a current VCSEL die 90 is considered not having expected performance. If D1 fulfills the requirement, the processor 19 identifies the polarization performance/stability of the VCSEL die 90 according to Residual and Rsquare (e.g., R²) of the light power data associated with a first polarization direction (e.g., D2) and the light power data associated with a second polarization direction (e.g., D3).

In one aspect, the testing system 100 of the present disclosure is connected to a screen to show all or a part of the above mentioned testing results, or to show statistical results of multiple dies.

It should be mentioned that although the present disclosure is described in the way that the first polarizer 151 is separated from the second light sensor 171 and the second beam splitter 132, and the second polarizer 152 is separated from the third light sensor 172 and the second beam splitter 132, the present disclosure is not limited thereto. In other aspects, the first polarizer 151 is combined to the second light sensor 171 or the second beam splitter 132, and the second polarizer 152 is combined to the third light sensor 172 or the second beam splitter 132 to achieve the same functions.

It should be mentioned that although the present disclosure is described in the way that the first beam splitter 131 and the second beam splitter 132 are 50/50 beam splitters, the present disclosure is not limited thereto. The first beam splitter 131 and the second beam splitter 132 may have other light splitting ratio as long as the thresholds are set correspondingly, e.g., including thresholds to be compared with Pmax, Pmax45 and Pmax0, thresholds to be compared with Ith, Ith45 and Ith0, thresholds to be compared with Max_Offset45 and Max_Offset0, and thresholds to be compared with differences Diff1 and Diff2.

It should be mentioned that the values, e.g., current values, light power values, power thresholds, a ratio of beam splitter and polarization directions, mentioned in the present disclosure are only intended to illustrate but not to limit the present disclosure.

As mentioned above, the conventional optical based goniometer system is impractical for production high-volume testing due extended test duration. Accordingly, the present disclosure further provides a testing system of a VCSEL die (e.g., referring to FIG. 1) and a testing method thereof (e.g., referring to FIG. 4) that identify the damage and angle rotation of a die according to tested light power of a non-polarized light beam and polarized light beams.

Although the disclosure has been explained in relation to its preferred embodiment, it is not used to limit the disclosure. It is to be understood that many other possible modifications and variations can be made by those skilled in the art without departing from the spirit and scope of the disclosure as hereinafter claimed.

1. A system for testing a vertical cavity surface emitting laser (VCSEL) die, the system comprising:
a first beam splitter, configured to split an emission light beam to a first light beam and a second light beam;
a second beam splitter, configured to split the second light beam to a third light beam and a fourth light beam;
a first polarizer, having a first polarization direction and configured for the third light beam to pass through;
a second polarizer, having a second polarization direction and configured for the fourth light beam to pass through;
a first light sensor, configured to receive the first light beam;
a second light sensor, configured to receive the polarized third light beam; and
a third light sensor, configured to receive the polarized fourth light beam.

2. The system as claimed in claim 1, wherein the first beam splitter and the second beam splitter are 50/50 beam splitters.

3. The system as claimed in claim 1, wherein a distance between the first beam splitter and the second beam splitter in a propagating direction of the second light beam is smaller than 1 mm.

4. The system as claimed in claim 1, wherein
one of the first and second polarization directions is 45 degrees, and
the other one of the first and second polarization directions is 0 degrees.

5. The system as claimed in claim 1, further comprising a source measure unit, wherein the source measure unit is configured to provide a driving current to the VCSEL die, and the driving current is increased by a predetermined step.

6. The system as claimed in claim 5, wherein
the driving current is increased from 0 to 9 mA, and
the predetermined step is 50 μA.

7. The system as claimed in claim 6, further comprising a processor configured to respectively calculate a fitting curve, a residual, a coefficient of determination and a threshold current offset of light power data of the second light sensor and the third light sensor.

8. A testing method of the system of claim 1, comprising:
driving the VCSEL die using a driving current increased by a predetermined step;
recording first light power data of the first light sensor, second light power data of the second light sensor, and third light power data of the third light sensor;
identifying whether the first light power data fulfills a predetermined power requirement or not;
calculating a second fitting curve of the second light power data and a third fitting curve of the third light power data upon the predetermined power requirement being fulfilled;
calculating a second residual data according to the second light power data and the second fitting curve; and
calculating a third residual data according to the third light power data and the third fitting curve.

9. The testing method as claimed in claim 8, wherein the first beam splitter and the second beam splitter are 50/50 beam splitters.

10. The testing method as claimed in claim 8, wherein
one of the first and second polarization directions is 45 degrees, and
the other one of the first and second polarization directions is 0 degrees.

11. The testing method as claimed in claim 10, further comprising:
identifying whether the second light power data is larger than the third light power data.

12. The testing method as claimed in claim 8, further comprising:
calculating a second coefficient of determination according to the second light power data, the second fitting curve and the second residual data; and
calculating a third coefficient of determination according to the third light power data, the third fitting curve and the third residual data.

13. The testing method as claimed in claim 12, further comprising:
identifying whether a maximum offset among the second residual data is within a second predetermined range; and
identifying whether a maximum offset among the third residual data is within a third predetermined range.

14. The testing method as claimed in claim 8, further comprising:
identifying whether a maximum power of the second power data is higher than a second power threshold; and
identifying whether a maximum power of the third power data is higher than a third power threshold.

15. The testing method as claimed in claim 8, further comprising:
calculating a second threshold current offset according to the second light power data; and
calculating a third threshold current offset according to the third light power data.

16. The testing method as claimed in claim 8, wherein the predetermined power requirement comprises:
a difference between a threshold current and a current at 1 mw of the first light power data fulfills a predetermined difference, and
a maximum power of the first light power data is higher than a first power threshold.

17. A testing method of a system for testing a VCSEL die, the system comprises a first light sensor, a second light sensor and a third light sensor, the testing method comprising:
outputting non-polarized light power data by the first light sensor;
outputting light power data associated with a first polarization direction by the second light sensor;
outputting light power data associated with a second polarization direction by the third light sensor;
identifying whether the non-polarized light power data fulfills a predetermined power requirement or not; and
identifying polarization performance of the VCSEL die according to residual data and coefficients of determination of the light power data associated with the first and second polarization directions upon the predetermined power requirement being fulfilled.

18. The testing method as claimed in claim 17, wherein
one of the first and second polarization directions is 45 degrees, and
the other one of the first and second polarization directions is 0 degrees.

19. The testing method as claimed in claim 18, further comprising:
identifying whether a maximum power of the light power data associated with the first polarization direction is higher than a second power threshold;
identifying whether a maximum power of the light power data associated with the second polarization direction is higher than a third power threshold; and
identifying whether the maximum power of the light power data associated with the first polarization direction is larger than that of the light power data associated with the second polarization direction.

20. The testing method as claimed in claim 17, further comprising:
calculating a second threshold current offset according to the light power data associated with the first polarization direction; and
calculating a third threshold current offset according to the light power data associated with the second polarization direction.
